(19) United States
(12) Patent Application Publication
(10) Pub. No.: US 2006/0192698 A1
(43) Pub. Date: Aug. 31, 2006

(54) Encoding dynamic graphic content views

(76) Inventor: Anthony Morel, Pont-A-Mousson (FR)

Correspondence Address: PHILIPS INTELLECTUAL PROPERTY & STANDARDS, P.O. BOX 3001, BRIARCLIFF MANOR, NY, 10510, US

(21) Appl. No.: 10/540,686

(22) PCT Filed: Dec. 29, 2003
(86) PCT No.: PCT/IB03/06249

§ 371 Date: Jan. 18, 2006

(30) Foreign Application Priority Data
Dec. 30, 2002 (CN) 02158390.0

(51) Int. Cl. H03M 7/30

(52) U.S. Cl. 341/87

(57) ABSTRACT

This invention relates to processing of dynamic graphic content, more particularly, to a method for pre-processing dynamic graphic content, a corresponding decoding method, and an apparatus for the same. The pre-processing method of the invention comprising: encoding a view in which all of the plurality of dynamic elements being in a first state as a reference picture; encoding the views in which at least one of the plurality of dynamic elements being in a state other than the first state as differential pictures with regards to said reference picture, to form a differential picture sequence; multiplexing said reference picture and said differential picture sequence together, and providing the result video signals. The method allows significant bandwidth and memory savings with only minor modifications to the user device.

### TECHNICAL FIELD

The present invention relates to processing of dynamic graphic content, in particular, to a method and apparatus for encoding/decoding dynamic graphic content.

### BACKGROUND OF THE INVENTION

Dynamic graphic content is rapidly prevailing with the rapid development of television meeting, VCD, digital TV and HDTV in recent years. The graphic content mentioned herein is a combination of text and pictures. The dynamic graphic content features such elements as forms, buttons, and targeted information, whose appearance is determined by the device on behalf of internal states and of its user.

As shown in FIG. 1, a known method for providing dynamic graphic content to end-users adds processing capabilities to the user device, so that it can render graphic content according to a description. In another word, the user device processes and renders the dynamic graphic content. Here, the dynamic graphic content can be described based on Digital TV standards such as OpenTV, MHP, to etc., or Internet standards such as HTML and extensions (such as JavaScript).

However, it is costly to add said processing capability to the user device. Typically, it demands more powerful CPUs, graphic co-processors, additional memory for code and data, and pixel-based picture memory. So dynamic graphic content is not accessible to low cost devices.

Another way as depicted in FIG. 3 is to pre-process the graphic content page by page, then multiplex the many video signals together, so that the content can be transmitted or stored in a digital video format. Such a method will be supported by user device naturally, without large modification to the user device. For example, the legacy MPEG decoder can be utilized. FIG. 2 schematically depicts a legacy MPEG decoder, in which, variable length decoder is denoted as VLD, inverse quantization as IQ, inverse discrete cosine transform as IDCT, and motion compensation as MC.

However, this method still has defects. In such a method, as many views as variants should be created according to the number of dynamic elements included in the dynamic graphic content. Suppose there are N dynamic elements in a dynamic graphic content, denoted as e_{I}, . . . ,e_{N}. Element eᵢ has Mᵢ different appearance states, denoted by 0, . . . ,M_{i-I}. Thus, the number of static views to create is equal to the product of Mᵢ (i=I˜N), denoted as Mᵢ in FIG. 3. This value will dramatically grow as N increases. For example, 10 elements with 2 states lead to 1024 (2¹⁰) views. Absolutely, bandwidth resource will be largely wasted in this way.

Therefore, a novel method for providing dynamic graphic content is required to compress dynamic pictures economically and effectively, and to save bandwidth and memory without large modifications to the user device.

### SUMMARY OF THE INVENTION

An object of the present invention is to solve the above-mentioned technical problems residing in the related art.

An aspect of the present invention provides a method for encoding dynamic graphic content in a block-based video predict-encoding scheme, comprising: encoding a view in which all of the plurality of dynamic elements being in a first state as a reference picture; encoding the views in which at least one of the plurality of dynamic elements being in a state other than the first state as differential pictures with regards to said reference picture, to form a differential picture sequence; multiplexing said reference picture and said differential picture sequence together, and providing the result video signals.

Preferably, the method for encoding dynamic graphic content of the invention is implemented in a MPEG encoding scheme.

Another aspect of the present invention provides a method for decoding video signals resulted from the method for encoding dynamic graphic content of the invention, comprising: decoding the reference picture; decoding the differential pictures corresponding to the state of dynamic elements that have changed with respect to said reference picture.

Preferably, the decoding method of the invention further comprising a step of skipping the differential pictures corresponding to the state of dynamic elements that has not changed with respect to said reference picture.

Still another aspect of the present invention provides a device for implementing the methods of the invention for encoding/decoding dynamic graphic content.

Still another aspect of the invention provides a broadcasting system and a video signals offering apparatus comprising the graphic encoding device of the invention.

Still another aspect of the invention provides a video player and a user device comprising the decoding device of the invention.

It will be appreciated that the method of the present invention can be applied to variant-predict encoding scheme, such as MPEG-1, 2, 4, DivX, H261, H262, H263, and H264, and the like.

### BRIEF DESCRIPTION OF THE DRAWINGS

The above and other objects, features and advantages of the invention will be more clearly understood from the following detailed description taken in conjunction with the accompanying drawings, in which:

FIG. 1 is a schematic block view showing a related user device having dynamic graphic content processing capability;

FIG. 2 is schematic block view showing a known MPEG decoder;

FIG. 3 is a block view illustrating the pre-processing of dynamic graphic content according to prior art;

FIG. 4 is a block view illustrating pre-processing of dynamic graphic content according to the present invention;

FIG. 5 is a diagram illustrating encoding all views by a single MPEG encoder;

FIG. 6 is a diagram illustrating the front end to the decoding method according to the present invention;

FIG. 7 is a flow chart showing the operation of the state machine shown in FIG. 12 and FIG. 13;

FIG. 8 explains the flow chart conventions used to depict finite state machines;

FIG. 9 is a diagram illustrating encoding all views by a single encoder using block/object coding and differential encoding;

FIG. 10 is a diagram illustrating an alternate implementation the encoding process depicted in FIG. 9, which said implementation results in fewer operations at the expense of an approximated result;

FIG. 11 is a schematic block view showing a known decoder for encoding schemes based on block/object coding and differential encoding;

FIG. 12 is a diagram illustrating how the known decoder depicted in FIG. 11 is modified to decode the dynamic graphic content according to the present invention.

FIG. 13 is a diagram illustrating how the known decoder depicted in FIG. 2 is modified to decode the dynamic graphic content according to the present invention.

### DETAILED DESCRIPTION OF THE EMBODIMENT

A detailed description to the embodiments of the present invention will be o provided as follows.

In a block (object)-based predict-encoding scheme, pictures are segmented into blocks (or objects), with each block occupying a constant area in the pictures. In the present invention, the pictures are segmented so that different dynamic elements are positioned in different blocks (objects). Each dynamic element occupies a constant area regardless of its states. This allows keeping the same layout in all variant views. The elements are non-overlapping not only in the pixel domain, but also in the coded domain. For example, MPEG-1 and MPEG-2 use block grids in encoding process, and different elements should fall on distinct blocks.

The preferred embodiment of the present invention will be described in detail by taking MPEG video encoding standards as an example for convenience sake. Please note that the MPEG encoding process scheme merely serves to explain the invention as a example, and is not intended to limit the invention. The method of the present invention can be applied to variant-predict encoding scheme, such as MPEG-1, 2, 4, DivX, H261, H262, H263, and H264, and the like.

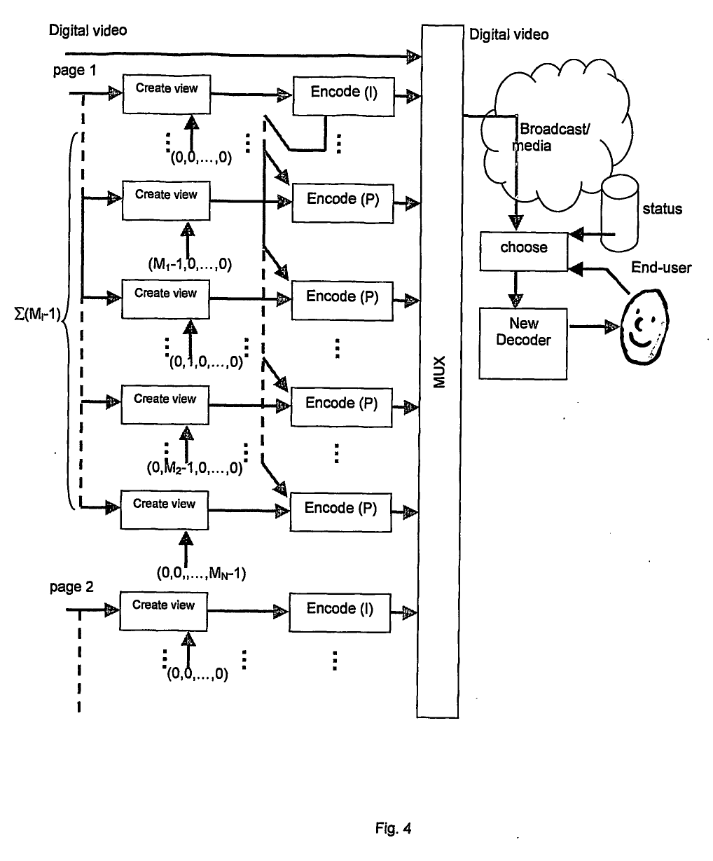

In the method of the present invention, view of (e₁=0, e₂=0, . . . ,e_{N}=0) is encoded as an Intra-picture (I-picture). Then views (e₁=l, e₂=0, . . . ,e_{N}=0), . . . ,(e₁=M₁−l, e₂=0, . . . ,e_{N}=0) are encoded as differential pictures with regards to the encoded view (e₁=0, e₂=0, . . . ,e_{N}=0). Here, differential encoding is the base of most video coding schemes, and especially the MPEG. Differential pictures are called P-pictures (predicted-pictures) in MPEG. The process continues for (e₁=0, e₂=l e₃=0, . . . ,e_{N}=0), . . . , (e₁=0, e₂=M₂−1, e₃=0, . . . , e_{N}=0) till (e₁=0, .. ., e_{N-1}=0, e_{N}=1), . . . , (e₁=0, . . . , e_{N-1}=0, e_{N}=M_{N}−1), see FIG. 4.

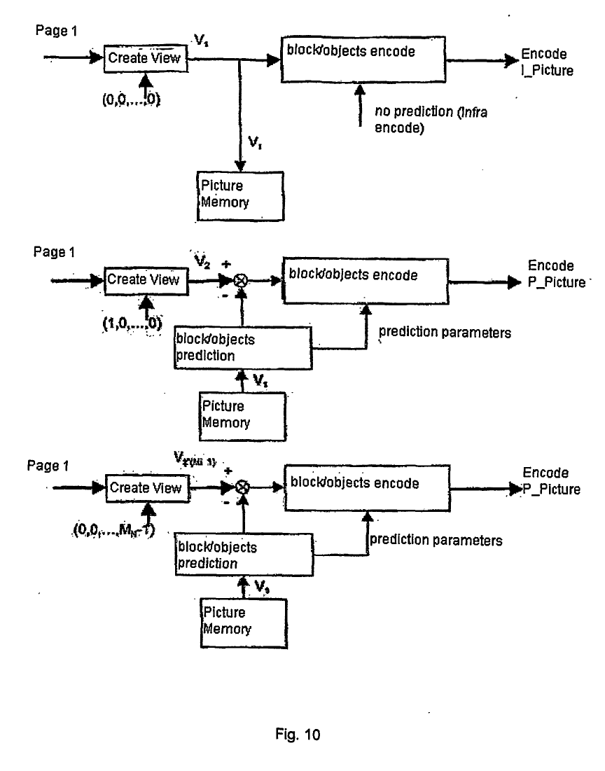

In encoding scheme using differential (or predictive) encoding, the above processing can be optimized by using a single encoder. This process is depicted in FIG. 9. First, the view (e₁=0, e₂=0, . . . , e_{N}=0), denoted as V₁, is encoded to a so-called infra-picture or I-picture. Blocks/objects in subsequent pictures are predicted using the decoded encoded version of V₁, denoted as V₁′. A variant of this process is depicted in FIG. 10. In said variant, blocks/objects in subsequent pictures are predicted using V₁ instead of V₁′. This variant is less complex and faster since it does not require decoding the encoded V₁ view. The system depicted in FIG. 9 and FIG. 10 achieves similar results for static block/objects within the views. However, the system in FIG. 10 leads to an approximated result for dynamic block/objects that are predicted from the reference picture. It can be chosen to force the prediction parameters to “no prediction” for such blocks, so that they are encoded without any reference to the reference picture.

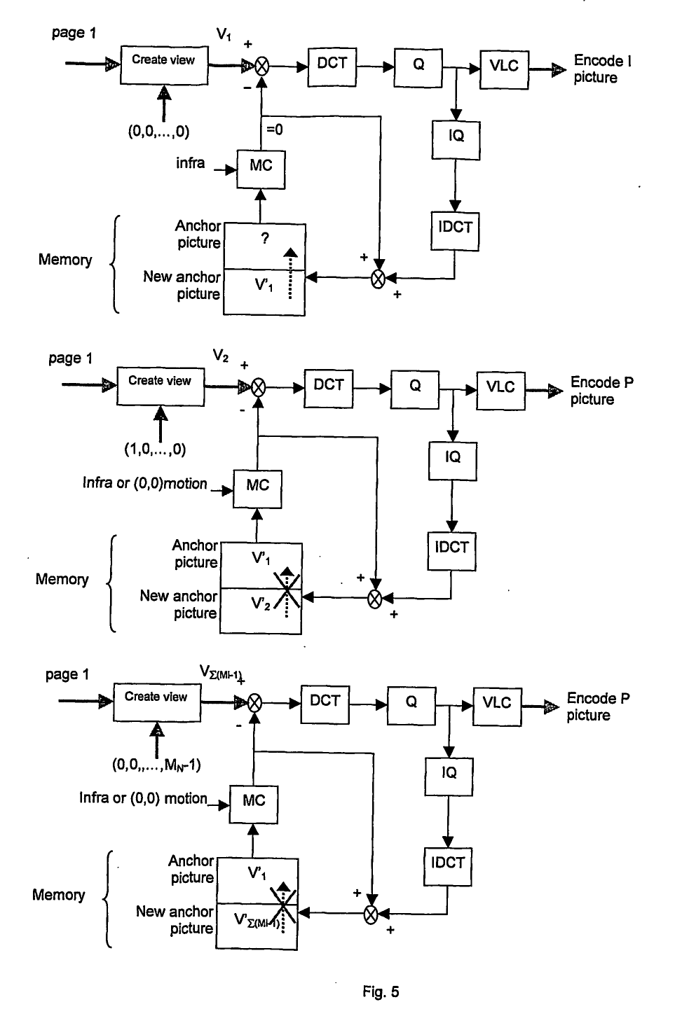

FIG. 5 shows the process of encoding all views using a single MPEG encoder, in which DCT denotes Discrete Cosine Transform, Q denotes Quantization, and VLC denotes Variable Length -Code Encoding. MPEG uses the latest encoded P-picture as the new anchor picture. But in the present invention, view V₁′ shall be kept as an anchor picture. As according to the MPEG process, both the anchor picture and the new anchor picture are in memory. Preferably, in processing of a dynamic graphic content, the update to the new anchor picture is disabled. No Motion Estimation is necessary in this embodiment. Anchors pictures, in the memory, are not used during the encoding of the I-picture. MC is set to “Infra”, which means that it does not issue any motion-compensated prediction for blocks to be encoded. As a consequence a null signal is the output of MC. The state of the input of MC is undefined. The decoded encoded I-picture, V₁′, enters the memory to become the new anchor picture. During the encoding of P-pictures, blocks are either encoded as “Intra” without any reference to the anchor. picture or as predicted blocks using data at the same position in the anchor picture, i.e., a (0,0) motion vector is used. The selection process is built in existing MPEG encoders. For example, it is based on the L1 distance (sum of absolute difference) between the block to predict and its prediction; for blocks encoded as “Intra”, the average value among the block is used as the prediction. The two distances are compared with a predetermined bias. The encoding which leads to the smallest biased distance is used. An encoder optimized to encode video signals specific to the invention with the minimum number of operations need not to perform the above computation. Such an encoder can use a-prior knowledge about the picture layout. In particular the static parts across views are optimally predicted with (0,0) motion vector, while the dynamic parts could sub-optimally always use “Intra” encoding or prediction with (0,0) motion vector.

This leads to an encoded video sequence formed by a group of 1 intra-picture +{Σ(Mᵢ−1) I=1, . . . ,N} predicted pictures. This sequence is short, so it is typically repeated in time until its content is outdated.

To further reduce bandwidth, preferably, the video signal contains an intra-picture !o no less than every predetermined time period. Predicted pictures, whose encoded forms are very compact, which simply indicate “no change with regards to previous picture”, can be added to the sequence if it is less than the predetermined time period. For example, for predetermined time period of ½ second at the rate of 25 pictures per second, the number of P-picture, {Σ(Mᵢ−1) i=1, . . . ,N}, should be 11. Here, the ½ second refers to the maximum latency for switching between views.

Table 1 below shows the comparison between the methods for dynamic graphic pre-processing of the present invention and the prior art, for a same latency between view switching at the receiver end.

TABLE 1

| | Prior art | The invention |
|---|---|---|
| I-picture | Product of Mᵢ | 1 |
| | (i = 1, . . . , N) | |
| Useful P-picture | 0 | Σ(Mᵢ − 1) |
| | | i = 1, . . . , N |
| “no change with regards | 11* product of Mᵢ | 11 − {Σ(Mi − 1) |
| to previous picture” | (i = 1, . . . , N) | i = 1, . . . , N} |

TABLE 2

| For N = 10 elements | | |
|---|---|---|
| with Mᵢ = 2 state | Prior art | The present |
| I-picture | 1024 | 1 |
| Useful P-picture | 0 | 10 |
| “no change with regards | 11*1024 | 1 |
| to previous picture” | | |

As can be seen, not only {Σ(Mᵢ−I) i=I, . . . , N) is significantly less than {product of Mᵢ i=1, . . . , N}, but also the size of P-pictures is an order of magnitude (10×) less than I-pictures. Thus, the pre-processing of dynamic graphic content of the prevent invention allows significant bandwidth savings.

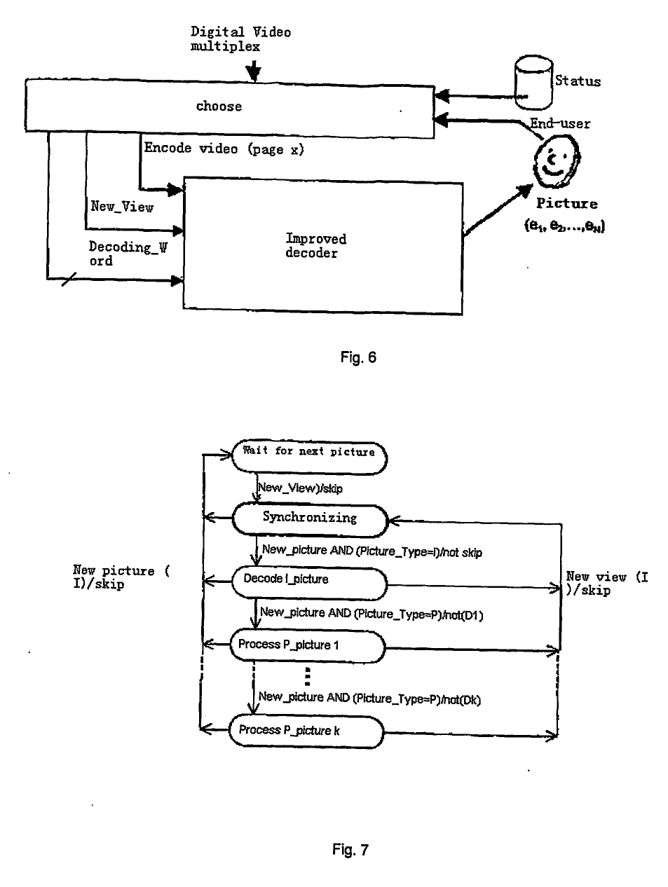

The decoding method of the present invention will be explained with reference to FIG. 6 to FIG. 8 and FIG. 12 to FIG. 13.

A legacy video decoder can play back the video signal encoded according to the method of the present invention.

To display the view corresponding to (e₁, e₂, . . . ,e_{N}) (where eᵢ is a value within 0, . . . ,Mᵢ−I denoting the appearance of the element), the decoder should first decode the I-picture before decoding P-picture. P-pictures encoding a state change in one of the elements can be denoted as the size N vector (0, . . . ,0, fᵢ≠0, 0, . . . ,0) where i is an index within 1˜N and fᵢ is the appearance of the element to within 0, . . . ,Mᵢ−I. Then, for all i such as eᵢ≠0, P-pictures (0, . . . ,0, fᵢ=eᵢ, 0, . . . ,0) will be decoded while other P-pictures will be skipped.

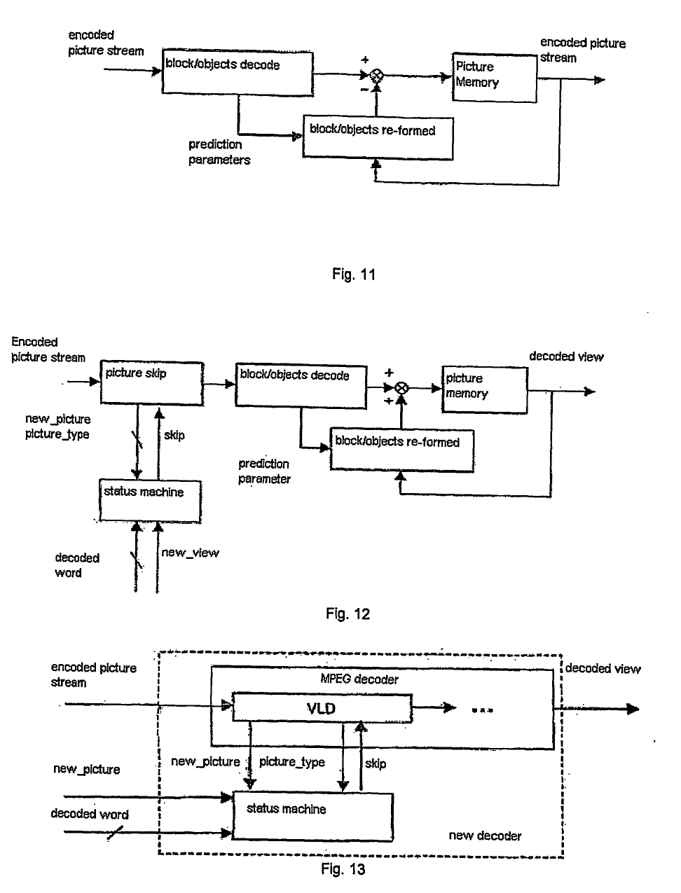

This decoding process can be performed in the decoder for encoding schemes based on block/object coding and differential encoding shown in FIG. 11 thanks small additions. In FIG. 12, we add to the decoder a block that allows skipping pictures. This block may pre-exist, for example, for error recovery. The block also detects the beginning of an encoded picture in the encoded picture stream (through the “New_Picture” signal) and can give its type (through the “Picture_Type” signal).

The state machine depicted in FIG. 7 can be used to control the skipping of picture based on inputs from the user interface, which are depicted in FIG. 6. The “New_View” signal indicates that a new view should be rendered and the “Decoding_Word” signal indicates P-Pictures to decode after the I-Picture. The “Decoding_Word” is computed from the view vector (e₁, e₂, . . . ,e_{N}), indicating the states of the N dynamic elements, where eᵢ is a value within 0, . . . ,Mⱼ−1. Let Decoding_Word be (Di, . . . ,D_{K}), where K=(Mᵢ−I)

$${D}_{1} = 1 if {e}_{1} = 1 , otherwise {D}_{1} = 0 \\ ...$$

$${D}_{{M}_{i} - 1} = 1 if {e}_{{M}_{i} - 1} = 1 , otherwise {D}_{{M}_{i} - 1} = 0 \\ {D}_{{M}_{i} - 1 + 1} = 1 if {e}_{2} = 1 , otherwise {D}_{{M}_{i} - 1 + 1} = 0 \\ ... \\ {D}_{{M}_{i} - 1 + {M}_{2} - 1} = 1 if {e}_{{M}_{2} - 1} = 1 , otherwise {D}_{{M}_{i} - 1 + {M}_{2} - 1 } = 0 \\ ... \\ {D}_{\sum ( {M}_{i} - 1 )} = 1 if {e}_{{M}_{N} - 1} = 1 , otherwise {D}_{\sum ( {M}_{i} - 1 )} = 0$$

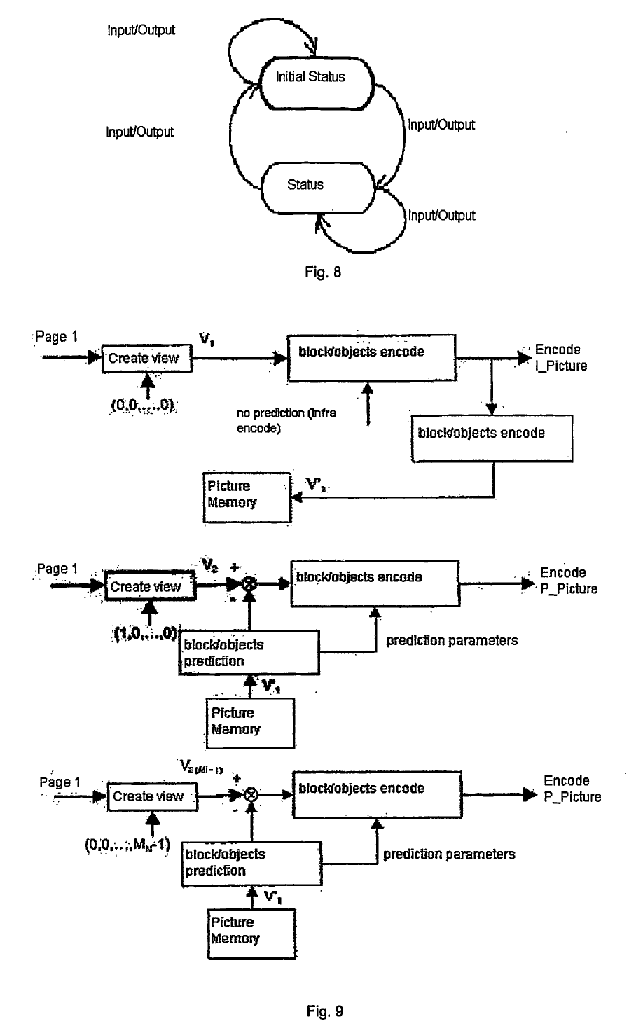

The state machine depicted in FIG. 7 has K+3 states, where K. (Mᵢ−1). Its initial state is “Synchronizing”, its inputs are {New_View, New_Picture, Picture_Type, Decoding_Word}, its output is Skip, with value (Don't Skip=0, Skip=I} depending on state and inputs, not( ) denotes the Boolean inversion function, i.e., not(I)=0 and not(0)=I. The representation conventions for state machines are depicted in FIG. 8.

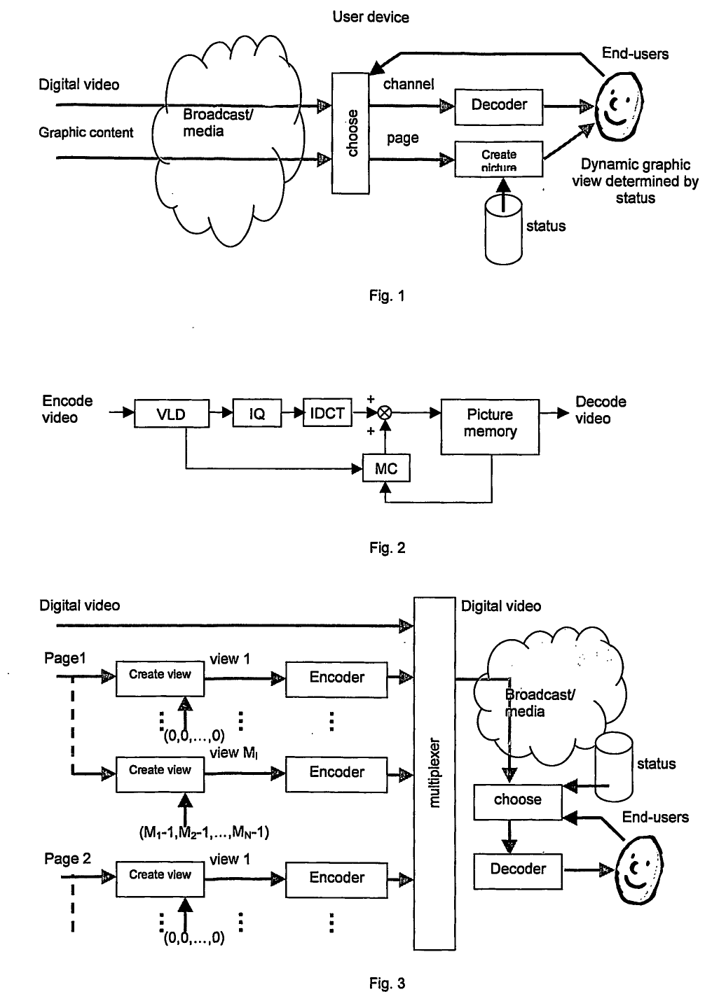

If the encoding scheme is MPEG, the decoding process can be performed thanks to slight modifications to the legacy MPEG decoder shown in FIG. 2. Such a decoder features a VLD (Variable-Length-Code Decoder) block, which is usually capable to skip picture, for example, for error recovery or trick play. In FIG. 13, we use the skip signal from the state machine to trigger the skip input of the VLD.

Once the desired view is constructed, it should be frozen on the screen until the graphic content changes. Typically, freezing a picture in decoding process is to conceal an erroneous stream, but in the present invention, it is a normal processing. For example, in a MPEG decoder, the VLD will wait for the synchronization word of the next picture while the last picture being frozen. The state machine in FIG. 7 will maintain the frozen state until a new view (signaled by the New View input) needs to be decoded.

So, the benefit of the decoding process of the present invention is that user device doesn't need to be re-designed significantly. In particular, this process can be performed in legacy video decoders.

Although the invention has been explained by taking MPEG encoding scheme as an example, it should be understood that, the MPEG scheme merely serves to explain the invention as an example, and is not intended to limit the invention. The invention can be conveniently applied to other block (object)-based predict-coding schemes. In addition, the details set above should not be deemed limitation to the invention. It is apparent for those skilled in the art that there are different substitutions, modifications and changes for the invention.

What is claimed is:

1. A method for encoding dynamic graphic content, said dynamic graphic content including a plurality of dynamic elements, each of which has a plurality of appearance states, the plurality of states of the plurality of elements lead to a plurality of views, said method comprising steps of:
encoding a view in which all of the plurality of dynamic elements being in a first state as a reference picture;
encoding remaining views in which at least one of the plurality of dynamic elements being in a state other than the first state as differential pictures with regards to said reference picture, to form a differential picture sequence; and
multiplexing said reference picture and said differential picture sequence together, and providing the resulting signals in video format.

2. The method of claim 1, wherein said method is implemented in the MPEG encoding scheme.

3. The method of claim 2, wherein said reference picture is an intra-picture, said differential pictures are predicted-pictures.

4. The method of claim 1, wherein said reference picture is cycled no less than every predetermined time period so that the bit rate of the resulting signals is reduced by a pre-selected factor.

5. The method of claim 1, further comprising a step of adding pictures indicating “no changes with regards to previous picture” into said differential picture sequence so as to reduce the bit-rate.

6. A method for decoding video signals resulted from the encoding method of claim 1, comprising steps of:
1) decoding said reference picture;
2) decoding the differential pictures corresponding to the state of dynamic elements that have changed with respect to said reference picture.

7. The method of claim 6, wherein said step (2) further comprising a step of skipping the differential pictures corresponding to the state of dynamic elements that have not changed with respect to said reference picture.

8. A method for providing dynamic graphic content, said dynamic graphic content including a plurality of dynamic elements, each of which has a plurality of appearance states, said method comprising steps of:
at the encoding side:
encoding a view in which all of the plurality of dynamic elements being in a first state as a reference picture;
encoding remaining views in which at least one of the plurality of dynamic elements being in a state other than the first state as differential pictures with regards to said reference picture, to form a differential picture sequence;
multiplexing said reference picture and said differential picture sequence together, and providing the resulting signals in video format,
at the decoding side:
decoding said reference picture;
decoding the differential pictures corresponding to the state of dynamic elements that have changed with respect to said reference picture, and skipping others.

9. A graphic encoding device comprising an encoder and a controller, wherein the controller controls the encoder to implement the following functions:
encoding a view in which all of the plurality of dynamic elements being in a first state as a reference picture;
encoding the views in which at least one of the plurality of dynamic elements being in a state other than the first state as differential pictures with regards to said reference picture, to form a differential picture sequence;
multiplexing said reference picture and said differential picture sequence together, and providing the result video signals.

10. A device for decoding the video signals encoded by the method of claim 1, comprising a decoder and a controller, wherein the controller controls the device to implement the following functions:
decoding said reference picture;
decoding the differential pictures corresponding to the state of dynamic elements that have changed with respect to said reference picture, and skipping others.

11. A broadcasting system comprising the graphic encoding device of claim 9.

12. An apparatus for offering video signals comprising the graphic encoding device of claim 9.

13. A video player comprising the decoding device of claim 10.

14. A user device comprising the decoding device of claim 10.
